(19) United States
(12) Patent Application Publication
(10) Pub. No.: US 2024/0014690 A1
(43) Pub. Date: Jan. 11, 2024

(54) ASSEMBLY OF NON-GALVANICALLY COUPLED ELECTRICAL NETWORKS AND METHOD FOR OPERATING SAME

(71) Applicant: BeXema GmbH, Magdeburg-Barleben (DE)

(72) Inventors: Hannes Benecke, Magdeburg (DE); Robert Benecke, Magdeburg (DE)

(21) Appl. No.: 18/018,602

(22) PCT Filed: Jul. 29, 2021
(86) PCT No.: PCT/DE2021/100651

§ 371 Date: Sep. 14, 2023

(30) Foreign Application Priority Data
Jul. 30, 2020 (DE) 10 2020 120 133.8

(51) Int. Cl. H02J 50/23; H02J 50/27

(52) U.S. Cl. CPC H02J 50/23; H02J 50/27

(57) ABSTRACT

Assembly of non-galvanically coupled networks, having two electrical networks and having a coupling device via which the electrical networks which are each galvanically connected to the coupling device by means of two connecting points are coupled to one another without being galvanically interconnected. The coupling device consists of two active electrical dipoles which are interconnected via at least one data link, can be operated both as a source and as a sink, and have measurement means for current and voltage. The dipoles are designed to provide current and/or voltage for the respective electrical network which are galvanically connected thereto in accordance with a target value received for this purpose from the respective other active electrical dipole, and to transmit the current and/or voltage values subsequently measured at the connecting points to the respective other active electrical dipole as a target value for the source/sink formed by this dipole.

The invention relates to an arrangement with networks coupled non-galvanically to each other, more precisely, an arrangement of two electrical networks and a coupling device, by means of which these two electrical networks are coupled to each other without creating a galvanic connection between them. The subject matter of the invention is the corresponding specially configured arrangement as well as a method for operating this arrangement.

For various reasons, technical arrangements exist in practice where two or possibly more electrical networks need to or should interact with each other, without thereby being galvanically connected to each other, that is, by means of electrical conductors. For example, arrangements in which two electrical networks or two electronic circuits are galvanically separated from each other for reasons of a required potential separation (such as a low-voltage network, on the one hand, and an electrical network with higher voltage or even a high-voltage network, on the other hand), yet are coupled in order to allow an interaction with each other by means of a transformer or an optocoupler, without sacrificing the galvanic separation, are very useful.

However, systems of the aforementioned kind and applications making use of them are not the starting point for the invention claimed and described in the following. A galvanic separation between electrical networks which should nevertheless interact with each other can also occur due to a great distance between the networks and thus the impracticality of a wireline connection of these networks, or also for other reasons making a direct (that is, a wireline) connection of the corresponding networks nearly impossible or at any rate inadvisable for practical reasons. In this context, the interaction of such electrical networks can also refer to an interplay on the electrically analog level, in addition to the case of a remote digital control process.

In view of the aforementioned aspect of a great distance existing between electrical networks interacting with each other, one may think of the case of an enterprise that manufactures different electronic components at dispersed locations, for example. For such an enterprise operating in a context of an international division of labor, or also multinationally, or for various enterprises cooperating with each other, it may be necessary, for example, to simulate and test in advance the interworking of two electrical networks, which need to be galvanically coupled together during their practical use, yet cannot be operated in this way during their testing, for instance, on account of development sites that are remote from each other.

The object of the invention is to provide a solution that makes possible an electrical interaction of electrical networks that are not or cannot be galvanically connected to each other. A corresponding arrangement for this and one possible method for operating this arrangement are to be stipulated.

The object is achieved by an arrangement having the features of patent claim 1. A method that achieves the task and that is carried out during the operation of such an arrangement is characterized by the independent method claim. Advantageous embodiments and enhancements of the arrangement are given by the dependent claims.

The technical solution proposed in regard to the above object relates to an arrangement of non-galvanically coupled networks composed of two electrical networks and a coupling device. By means of said coupling device, each of the two electrical networks is galvanically connected to two particular connection points. The coupling device couples the two electrical networks to each other, but without connecting them galvanically to each other.

According to the invention, the coupling device for this is composed of two sources/sinks which are typically at a distance from each other, being connected to each other across at least one data connection, but non-galvanically. These sources/sinks involve two active electrical dipoles which can be operated both as source and as sink. The two active electrical dipoles are each outfitted with measurement means for measuring the current intensity and the voltage, having at least one control and processing device (hereinafter and in the patent claims, also referred to as SVE) and having at least one data transmitting and receiving device. The active electrical dipoles are configured to:
a.) provide current and/or voltage for the respective electrical network connected to them, under the control of their respective SVE (each active electrical dipole has its own SVE), according to a nominal value received from the other particular active electrical dipole and
b.) then record as measurement values the values being set for current and/or voltage at the connection points of the electrical network galvanically connected to the active electrical dipole receiving the nominal value as measurement values and digitize these measurement values by means of its respective SVE and
c.) transmit digitized measurement values for current and/or voltage by means of its respective data transmitting and receiving device to the other particular dipole as the nominal value for the source/sink formed by this dipole.

The (non-galvanic) coupling of the two electrical networks that may also be possibly far apart from each other (for example, at a distance of many, perhaps hundreds of kilometers) therefore does not occur traditionally, in the electrical sense, but by means of a data connection. This data connection exists between the two typically far-distanced active electrical dipoles, which are together referred to as a coupling device based on their interaction.

Because of the fact that measurement values for current and/or voltage that are registered at the connection points of one of the electrical networks connected to the coupling device are transmitted by the data connection as nominal values to the other respective electrical network and current and/or voltage corresponding to this nominal value are provided by the source/sink galvanically connected to it, i.e., by the portion of the coupling device galvanically connected to it, and thus current and/or voltage are imposed to a certain extent by one of the electrical networks on the other respective electrical network, the arrangement so produced is comparable, in terms of the resulting ratios, to an arrangement in which the two electrical networks are directly galvanically connected to each other. As shall be made even more clear in the course of the remarks on the method, this latter effect occurs especially when current values and/or voltage values are exchanged repeatedly as nominal values between the two electrical networks across the coupling device having the data connection.

The above-represented approach to a solution in this form can be applied basically regardless of whether the two electrical networks non-galvanically coupled to each other by means of the coupling device are networks operating by direct current or alternating current. However, it should be taken into account that the kind of coupling of the networks by means of a data connection and the processes required in this regard, such as a digitization of the values being transmitted respectively for current and/or voltage and the actual transmission itself, will introduce a certain latency.

Of course, it is possible to take this latency into account during the synchronization basically carried out between the two electrical networks according to the invention, according to the preceding remarks (a synchronization in terms of the current and/or voltage). However, this is the case when the latency is approximately constant. Depending on the distance between the two electrical networks and the kind of data connection used in the coupling device for the coupling, however, such a constancy is not always present, and furthermore the transmission of the digitized measurement values for current and/or voltage may also be subject to perturbations.

Against this background, it may be difficult, if not impossible, to realize a coupling of electrical networks with rapidly changing current and voltage ratios, such as in the case of an alternating current operation, by using the solution according to the invention. Therefore, the focus of the proposed solution is placed accordingly on an especially practice-relevant embodiment in which the two electrical networks coupled non-galvanically by means of the coupling device according to the invention are networks operated by direct current, or networks in which stationary or quasi-stationary ratios are established over certain periods of time. However, it should be expressly pointed out that the invention is not limited thereto.

In regard to an especially preferred use, in one possible embodiment of the arrangement according to the invention, one of the electrical networks coupled by means of the coupling device is an active network with a voltage source and the other network is a passive network forming an electrical load for the active network with the voltage source. The voltage source in the active electrical network or a sink can furthermore be operated in different modes, depending on the use intended for the particular electrical network. The source/sink can be operated in voltage mode, with a constant voltage being provided, or in current mode, with a constant current being provided, in power mode with constant power being provided, or in resistance mode, where the source behaves like a variably adjustable, yet constant, resistance.

Especially if one of the electrical networks coupled together is an active network with a voltage source operating in power mode, one embodiment of the arrangement according to the invention will be used in which the sources/sinks of the coupling device are configured as 4-quadrant sources/sinks. Four-quadrant sources/sinks are electronic components which, unlike classical network devices, can produce both positive and negative voltages and also provide positive and negative currents for other electrical devices/units and can take up such currents—acting as a sink—from other electrical devices/units.

The arrangement according to the invention can also be advantageously enhanced in that at least one of the sources/sinks of the coupling device has means for plotting the time curve of the values being set for the current and/or voltage as registered by the measurement means at the common connection points with the corresponding electrical network. This is relevant in particular for a configuration of the arrangement for testing or simulation purposes, i.e., in the context of scenarios where the course of the synchronization of current and/or voltage taking place between the two electrical networks shall be considered and possibly further evaluated.

In one especially advantageous enhancement, therefore, at least one of the sources or sinks of the coupling device has means for visualization of the respective measured values for current and/or voltage at the common connection points with the corresponding electrical network and/or a visualization of their time curve. The corresponding measurement values and/or their time curve are processed for purposes of the visualization by the SVE of the corresponding source/sink of the particular active dipole (electrical dipole), i.e., the corresponding portion of the coupling device.

The at least one data connection that connects the two active electrical dipoles to each other for the transmission of the digitized values for current and/or voltage serving as nominal values can be, for example, a mobile radio connection or a special data-radio connection. For cost considerations, especially in the case of very distant electrical networks non-galvanically coupled by means of the coupling device, possibly being situated in different countries or even on different continents, this can also be an Internet connection. Given an appropriate configuration and design of the SVEs provided in the active electrical dipoles of the coupling device and controlling the data transmission by their transmitting and receiving devices, the invention also encompasses the possibility of multiple data connections existing between the active dipoles, possibly at the same time, and possibly also realized by different media.

According to the method proposed in order to achieve the object, the two active electrical dipoles of the coupling device continuously register measurement values for current and/or voltage at the connection points of the respective electrical network galvanically connected to them and transmit them, after being digitized, alternately to the particular other active electrical dipole as the nominal value for the electrical source/sink formed by them. That is, the two dipoles continuously synchronize the current and/or voltage with each other, depending on the type of operation (voltage mode, current mode, power mode or resistance mode), and these values are thereby adjusted as though the networks are directly galvanically connected to each other at their connection points to the coupling device.

Of course, this process is also influenced by the latency caused by the measurement of the values, their digitization, and the transmission by the data connection, so that a current and/or a voltage varying in one of the networks has effects only after a certain delay in the other respective network. Because of the fact that the other dipole receiving the nominal value or values transmits in turn the values established in response to the providing of the particular current and/or the particular voltage at the connection points of its corresponding electrical network (as the system response of the particular network) as nominal values to the other respective dipole and the receiving portion of the arrangement also responds to this with a certain delay, the overall system oscillates to a certain extent after a corresponding change in the current and/or voltage ratios in one of the two electrical networks.

According to one possible implementation of the method according to the invention, the latter serves for detecting and observing the interaction of two electrical networks connected to each other by means of the coupling device according to the invention. One possible use is to analyze the ratios established for current and voltage in the interaction between a motor vehicle battery, as part of an active electrical network, and a passive electrical network arranged at a distance from it, at least during the corresponding testing, such as an electric motor with inverter, prior to the later joining together of these two components.

The invention shall be further explained in the following with the aid of figures in the manner of an exemplary embodiment. The individual drawings show specifically:

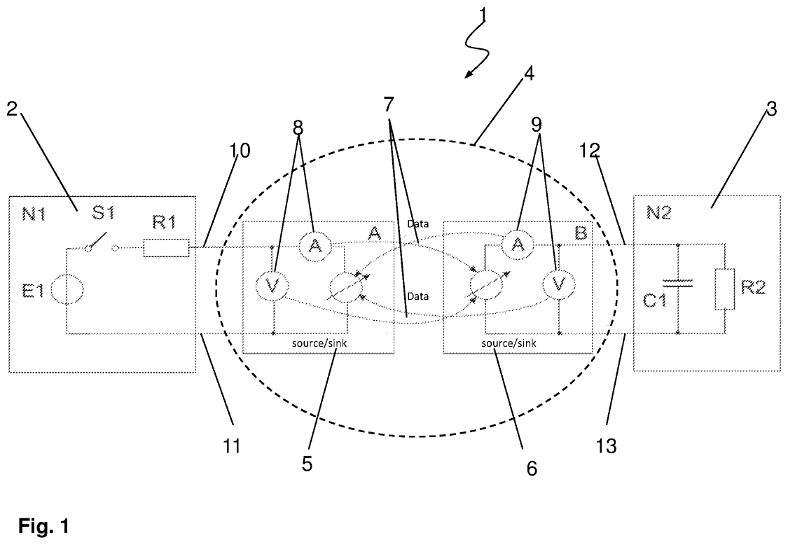

FIG. 1: a block diagram of one possible embodiment of the arrangement according to the invention,

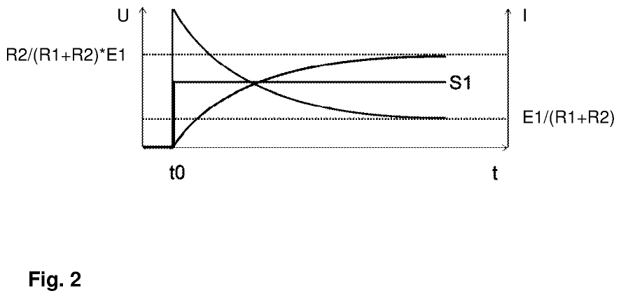

FIG. 2: a diagram with the time course adjusted for current and voltage in one of the networks after a change of state,

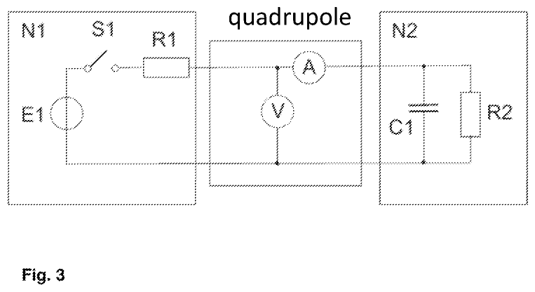

FIG. 3: a symbolic circuit diagram for the layout virtually existing in the arrangement of FIG. 1.

FIG. 1 shows a rough block diagram of one possible embodiment of the arrangement 1 according to the invention. The arrangement 1 is composed of the first electrical network 2 (N1), the second electrical network 3 (N2) and the coupling device 4, non-galvanically coupling the two electrical networks 2, 3 to each other, yet still galvanically connecting the two electrical networks 2, 3. The example shown in FIG. 1 for the electrical network 2 (N1) shown at the left is an active network with a voltage source. On the other hand, the electrical network 3 (N2) shown at the right is a passive network, forming a load for the voltage source (El) of the active network 2 (N1) in a direct galvanic connection of the two networks 2, 3 in the classical sense. Thanks to the invention, however, and the special kind of non-galvanic coupling of the two electrical networks 2, 3, the passive network 3 (N2) shown at right in the arrangement shown in the figure likewise acts as a load for the active electrical network 2 (N1) shown at left, despite no galvanic connection existing between the electrical networks 2, 3.

The coupling device 4 is composed of two active electrical dipoles 5, 6, each of which can be operated as both a source and a sink, being connected to each other not galvanically, but by a data connection 7, that is, they are coupled to each other. Each of these active electrical dipoles 5, 6 has a control and processing device (SVE), not shown in the drawing, a data transmitting and receiving device (likewise not shown) to establish the mentioned data connection, and measurement means 8, 9 for registering the current and voltage in the particular associated electrical network 2, 3. The particular electrical network 2, 3 is galvanically connected to the respective corresponding portion of the coupling device 4 by two connection points or 12, 13.

FIG. 2 shows the current and voltage ratios (with voltage=U and current (intensity)=I) such as they are adjusted in a variation over time both at the connection points 10, 11 connecting the active electrical network 2 (N1) (shown at the left) to the corresponding portion of the coupling device 4 and at the connection points 12, 13 connecting the passive electrical network 3 (N2) (shown at the right) to the corresponding portion of the coupling device 4 after the closing of the switch S1 in the active electrical network 2 (N1). The corresponding ratios with the end voltage value R2/(R1+R2)*E1 and the end current value E1/(R1+R2) are typically adjusted within around 0.5 ms to 15.0 ms from the closing of the switch S1, depending on the kind of data connection 7 and the given latency during its use. After the closing of this switch S1 of the active electrical network 2 (N1) with the voltage source El operating in power mode, the current intensity (I) and the voltage (U) are measured by the corresponding portion (active electrical dipole 5) of the coupling device 4 by way of its measurement means 8. The corresponding measurement values are digitized by the SVE (not shown) of this portion (the active electrical dipole 5) of the coupling device 4 and transmitted as nominal values by its data transmitting and receiving device (likewise not shown) to the other active electrical dipole 6 of the coupling device 4 galvanically connected to the passive electrical network 3 (N2), shown at the right. The active electrical dipole 6 receiving these nominal values and forming a source/sink adjusts a current and a voltage corresponding to these nominal values for the passive electrical network 3 (N2) with the resistor R2 and the capacitor C1 hooked up in parallel with it and then for its part measures the current intensity and the voltage at the connection points 12, 13 for this passive electrical network 3 (N2) as a system response, in order to then transmit in turn its digitized values as nominal values to the other active electrical dipole 5 associated with the active electrical network 2 (N1) represented at the left side of the figure. This cycle is repeated constantly with a very short cycle time (in the microsecond range), so that the ratios represented in FIG. 2 are then adjusted.

FIG. 3 shows a symbolic circuit diagram of a configuration that is formed more or less in virtual form by the arrangement of FIG. 1. Accordingly, the arrangement of FIG. 1 (disregarding the latencies) works as though the two electrical networks are connected galvanically to each other at their connection points across a quadrupole. It becomes clear from the drawing that the coupling device of the arrangement according to the invention, shown in FIG. 1, more or less partitions the quadrupole (indicated symbolically in FIG. 3) into two active electrical dipoles. In order not to give the impression that the configuration according to the symbolic diagram of FIG. 3 involves an alternative embodiment to the arrangement of FIG. 1, reference numbers have been deliberately omitted.

1. An arrangement (1) of non-galvanically coupled networks (2, 3), comprising two electrical networks (2, 3) and a coupling device (4) by which the two electrical networks (2, 3), each connected galvanically to the coupling device (4) by two connection points (10, 11 and 12, 13), are electrically coupled to each other, without themselves being galvanically connected to each other, is hereby characterized in that the coupling device (4) is composed of two sources/sinks connected to each other by at least one data connection (7), but not coupled galvanically, namely, is composed of two active electrical dipoles (5, 6) that can operate as both source and sink, each of them being outfitted with measurement means (8, 9) for current and voltage, having at least one control and processing device SVE and having at least one data transmitting and receiving device, wherein the two active electrical dipoles (5, 6) are adapted to
a.) provide current and/or voltage for the respective electrical network (2, 3) galvanically connected to them, under the control of their respective SVE, according to a nominal value received from the other particular active electrical dipole (5, 6) and
b.) then record as measurement values the values being adjusted for current and/or voltage at the connection points (10, 11 or 12, 13) of the electrical network (2, 3) galvanically connected to an active electrical dipole (5, 6) receiving the nominal value as measurement values and digitize them by means of its respective SVE and
c.) transmit digitized measurement values for current and/or voltage by means of its respective data transmitting and receiving device via the data connection (7) to the other particular active electrical dipole (5, 6) as the nominal value for the source/sink formed by this active electrical dipole (5, 6).

2. The arrangement according to claim 1, further characterized in that the electrical networks (2, 3) are electrical networks (2, 3) operating with direct current.

3. The arrangement according to claim 1, further characterized in that the sources/sinks of the active electrical dipoles (5, 6) are each configured as 4-quadrant sources/sinks.

4. The arrangement according to claim 1, further characterized in that at least one of the active electrical dipoles (5, 6) forming a source/sink has means of plotting the time curve of the values being adjusted for the current and/or voltage as registered by its measurement means (8, 9) at the common connection points (10, 11, 12, 13) with the corresponding electrical network (2, 3).

5. The arrangement according to claim 1, further characterized in that at least one of the active electrical dipoles (5, 6) forming a source/sink has means of visualization of the respective measured values for current and/or voltage at the common connection points (10, 11, 12, 13) with the corresponding electrical network (2, 3) and/or a visualization of their time curve, wherein the measurement values and/or their time curve are processed for the visualization by the SVE of the corresponding portion of the coupling device (4).

6. The arrangement according to claim 1, further characterized in that one of the electrical networks (2, 3) coupled by means of the coupling device (4) is an active network (2) with a voltage source operating in power mode and the other network (3) is a passive network forming an electrical load for the active network (2) with the voltage source.

7. The arrangement according to claim 1, further characterized in that the data connection (7) which connects the two active electrical dipoles (5, 6) to each other involves a mobile radio connection.

8. The arrangement according to claim 1, further characterized in that the data connection (7) which connects the two active electrical dipoles (5, 6) to each other is an Internet connection.

9. A method for operating an arrangement (1) according to claim 1, is hereby characterized in that the two active electrical dipoles (5, 6) of the coupling device (4) continuously register and digitize measurement values for current and/or voltage at the connection points (10, 11, 12, 13) of the respective electrical network (2, 3) galvanically connected to them and in that the active electrical dipoles (5, 6) alternately transmit the digitized measurement values to the particular other active electrical dipole (5, 6) as the nominal value for the electrical source/sink formed by them so that the current and/or voltage at the connection points (10, 11, 12, 13) of the two electrical networks (2, 3) connected to the coupling device (4) are adjusted in such a way as if the networks (2, 3) are galvanically connected to each other at these connection points (10, 11, 12, 13).
